(19) United States
(12) Patent Application Publication
(10) Pub. No.: US 2026/0026091 A1
(43) Pub. Date: Jan. 22, 2026

(54) SEMICONDUCTOR DEVICES COMPRISING BACKSIDE POWER DELIVERY NETWORK STRUCTURE

(71) Applicant: Samsung Electronics Co., Ltd., Suwon-si (KR)

(72) Inventors: HYUNSOO KIM, Suwon-si (KR); DONGHOON HWANG, Suwon-si (KR); JAEHO JEON, Suwon-si (KR); MINWOO KIM, Suwon-si (KR); SEONGKWANG KIM, Suwon-si (KR)

(21) Appl. No.: 19/037,874

(22) Filed: Jan. 27, 2025

(30) Foreign Application Priority Data
Jul. 19, 2024 (KR) 10-2024-0095590

(51) Int. Cl. H10D 84/83; H10D 30/00; H10D 30/01; H10D 30/43; H10D 62/10; H10D 62/13; H10D 64/23; H10D 84/01

(52) U.S. Cl. CPC H10D 84/832; H10D 30/43; H10D 30/502; H10D 62/116; H10D 62/121; H10D 62/151; H10D 64/256; H10D 30/014; H10D 30/0191; H10D 84/0149; H10D 84/0151

(57) ABSTRACT

A semiconductor device includes a substrate insulating layer including an insulating pattern, a first gate structure and a second gate structure overlapping the insulating pattern, first semiconductor patterns spaced apart from each other and second semiconductor patterns spaced apart from each other, first and second source/drain regions respectively connected to the first and second semiconductor patterns, a first separation pattern extending between the first and second gate structures, the first separation pattern insulating the first and second gate structures from each other, a second separation pattern extending into respective at least portions of ones of the first semiconductor patterns and ones of the second semiconductor patterns, and a backside contact plug extending into the substrate insulating layer and connected to at least some of the source/drain regions. At least one of the first and second separation patterns includes an air gap.

### CROSS-REFERENCE TO RELATED APPLICATIONS

This application claims the benefit under 35 USC 119(a) of Korean Patent Application No. 10-2024-0095590 filed on Jul. 19, 2024 in the Korean Intellectual Property Office, the entire disclosure of which is incorporated herein by reference for all purposes.

### BACKGROUND OF THE INVENTION

The present inventive concept relates to semiconductor devices.

As demand for high performance, high speed, and/or multifunctionality of semiconductor devices increases, the degree of integration of semiconductor devices is increasing. With the trend for a high degree of integration of semiconductor devices, efforts are being made to develop semiconductor devices including FinFETs including fin-shaped channels and Gate-All-Around field effect transistors including nanosheets surrounded by gates, and semiconductor devices having a BackSide Power Delivery Network (BSPDN) structure in which power rails are disposed on the backside of a wafer.

### SUMMARY OF THE INVENTION

Example embodiments may provide semiconductor devices having improved electrical characteristics.

According to example embodiments, a semiconductor device includes a substrate insulating layer that includes an insulating pattern, wherein the insulating pattern extends in a first direction that is parallel with a lower surface of the substrate insulating layer, and the insulating pattern protrudes in a third direction that is perpendicular to the lower surface of the substrate insulating layer; a first gate structure that extends in a second direction that is parallel with the lower surface of the substrate insulating layer and intersects the first direction, wherein the first gate structure overlaps the insulating pattern in the third direction; a second gate structure that extends in the second direction and is spaced apart from the first gate structure in the first direction, wherein the second gate structure overlaps the insulating pattern in the third direction; first semiconductor patterns that are spaced apart from each other in the third direction, wherein the first gate structure extends around the first semiconductor patterns; second semiconductor patterns that are spaced apart from each other in the third direction, wherein the second gate structure extends around the second semiconductor patterns; a plurality of source/drain regions that includes a first source/drain region and a second source/drain region on the insulating pattern, wherein the first source/drain region is electrically connected to the first semiconductor patterns, and the second source/drain region is electrically connected to the second semiconductor patterns; a first separation pattern that extends in the third direction between the first gate structure and the second gate structure; a plurality of second separation patterns, ones of which extend into at least portions of the respective ones of the first semiconductor patterns and/or the respective ones of the second semiconductor patterns in the third direction; and a backside contact structure that extends into the substrate insulating layer, wherein the backside contact structure is electrically connected to at least one of the plurality of source/drain regions, wherein at least one of the first separation pattern and the plurality of second separation patterns includes an air gap and an insulating liner, and wherein a side surface of the insulating liner extends along at least a portion of a boundary of the air gap.

According to example embodiments, a semiconductor device includes a substrate insulating layer that includes an insulating pattern that protrudes in a direction that is perpendicular to a lower surface of the substrate insulating layer; a first gate structure and a second gate structure on the substrate insulating layer, wherein the first gate structure and the second gate structure overlap the insulating pattern, and wherein the first gate structure and the second gate structure are spaced apart from each other; a plurality of semiconductor patterns that are stacked and spaced apart from each other in the direction, wherein the first gate structure and/or the second gate structure extend around ones of the plurality of semiconductor patterns; source/drain regions on the substrate insulating layer, wherein the source/drain regions are in contact with opposite side surfaces of the plurality of semiconductor patterns; a plurality of separation patterns that are configured to separate the first gate structure and the second gate structure into a plurality of regions and electrically insulate the plurality of regions from each other; and a backside contact plug that extends into the substrate insulating layer and is electrically connected to at least one of the source/drain regions, wherein the plurality of separation patterns include a first separation pattern that has a first length and a second separation pattern that has a second length equal to or greater than the first length, wherein the first separation pattern includes a first material and the second separation pattern includes a second material, and wherein a dielectric constant of the first material is equal to or greater than a dielectric constant of the second material.

According to example embodiments, a semiconductor device includes a first transistor that includes a first gate electrode, a first gate dielectric layer, a first source/drain region, a second source/drain region, and first semiconductor patterns; a second transistor that includes a second gate electrode, a second gate dielectric layer, a third source/drain region, a fourth source/drain region, and second semiconductor patterns, wherein the second transistor is spaced apart from the first transistor; a first separation pattern between the first transistor and second transistor, wherein the first separation pattern electrically insulates the first gate electrode and the second gate electrode from each other; second separation patterns that extend into at least portions of the first gate electrode and the second gate electrode, wherein the second separation patterns are configured to divide each of the first gate electrode and the second gate electrode into two sub-regions; and a backside contact plug that is electrically connected to at least one of the first source/drain region, the second source/drain region, the third source/drain region, and the fourth source/drain region, wherein at least one of the first separation pattern and the second separation patterns includes an air gap region and an insulating liner adjacent the air gap region and extends continuously without a step.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to example embodiments;

FIG. 2A is a cross-sectional view taken along line I-I′ of the semiconductor device of FIG. 1, FIG. 2B is a cross-sectional view taken along line II1-II1′ of the semiconductor device of FIG. 1, and FIG. 2C is a cross-sectional view taken along line II2-II2′ of the semiconductor device of FIG. 1;

FIG. 3A is a cross-sectional view taken along line I-I′ of a semiconductor device corresponding to line I-I′ of the semiconductor device of FIG. 1 according to example embodiments, FIG. 3B is a cross-sectional view taken along line II1-II1′ of a semiconductor device corresponding to line II1-II1′ of the semiconductor device of FIG. 1 according to example embodiments, and FIG. 3C is a cross-sectional view taken along line II2-II2′ of a semiconductor device corresponding to line II2-II2′ of the semiconductor device of FIG. 1 according to example embodiments;

FIG. 4A is a cross-sectional view taken along line I-I′ of a semiconductor device corresponding to line I-I′ of the semiconductor device of FIG. 1 according to example embodiments, FIG. 4B is a cross-sectional view taken along line II1-II1′ of a semiconductor device corresponding to line II1-II1′ of the semiconductor device of FIG. 1 according to example embodiments, and FIG. 4C is a cross-sectional view taken along line II2-II2′ of a semiconductor device corresponding to line II2-II2′ of the semiconductor device of FIG. 1 according to example embodiments;

FIGS. 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, and 17C are cross-sectional views illustrated according to the process order to describe a method of manufacturing a semiconductor device according to example embodiments;

FIGS. 18A, 18B, 18C, 19A, 19B, and 19C are cross-sectional views illustrated according to the process order to describe a method of manufacturing a semiconductor device according to example embodiments; and

FIGS. 20A, 20B, and 20C are cross-sectional views illustrated according to the process order to describe a method of manufacturing a semiconductor device according to example embodiments.

### DETAILED DESCRIPTION

Spatially relative terms, such as “beneath,” “below,” “lower,” “above,” “upper,” “higher” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly. The term “and/or” includes any and all combinations of one or more of the associated listed items.

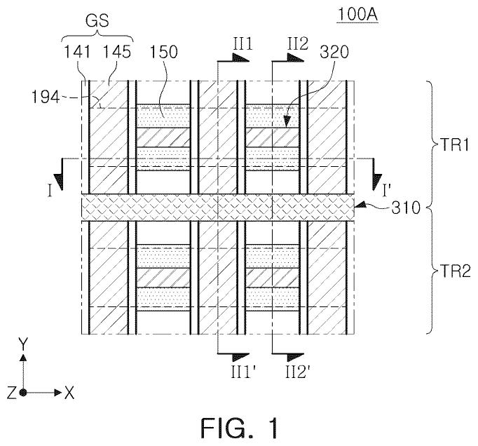

FIG. 1 is a plan view illustrating a semiconductor device 100A according to example embodiments.

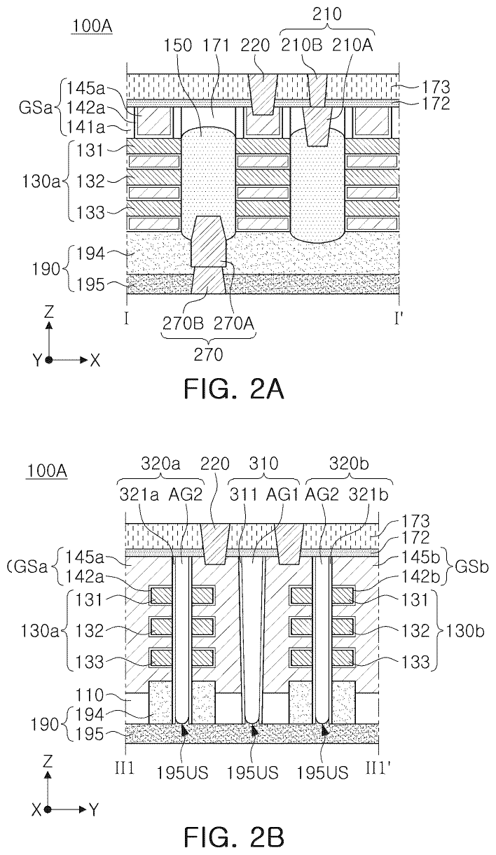

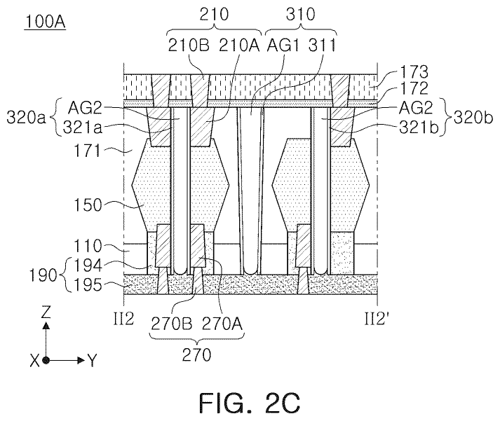

FIG. 2A is a cross-sectional view of the semiconductor device 100A of FIG. 1 taken along line I-I′, FIG. 2B is a cross-sectional view of the semiconductor device 100A of FIG. 1 taken along line II1-II1′, and FIG. 2C is a cross-sectional view of the semiconductor device 100A of FIG. 1 taken along line II2-II2′. For the convenience of explanation, descriptions and details of well-known (or non-essential) steps and components of the semiconductor device may be omitted in FIGS. 1, 2A, 2B, and 2C.

Referring to FIGS. 1, 2A, 2B, and 2C, a semiconductor device 100A according to example embodiments may include a substrate insulating layer 190 that includes a protruding insulating pattern 194 (also referred to as a first insulating material layer 194), first and second gate structures GSa and GSb disposed to be spaced apart from each other, first and second semiconductor patterns 130a and 130b disposed to be surrounded by the first and second gate structures GSa and GSb, respectively, source/drain regions 150, a first separation pattern 310 between the first and second gate structures GSa and GSb to insulate (e.g., electrically separate) the first and second gate structures GSa and GSb from each other, a second separation pattern 320 respectively extending in (e.g., penetrating) at least portions of the first semiconductor patterns 130a and the second semiconductor patterns 130b, and a backside contact structure 270 extending in (e.g., penetrating) (at least a portion of) the substrate insulating layer 190 and (electrically) connected to at least portions of the source/drain regions 150. For example, the first and second gate structures GSa and GSb may at least partially extend around the first and second semiconductor patterns 130a and 130b, respectively. The semiconductor device 100A according to the present embodiment may further include a device isolation layer 110, a frontside contact structure 210 extending in (e.g., penetrating) at least a portion (e.g., the upper surface) of at least one of the source/drain regions 150 and (electrically) connected to at least one of the source/drain regions 150, and second and third interlayer insulating layers 172 and 173 disposed on the upper surfaces of the first and second gate structures GSa and GSb.

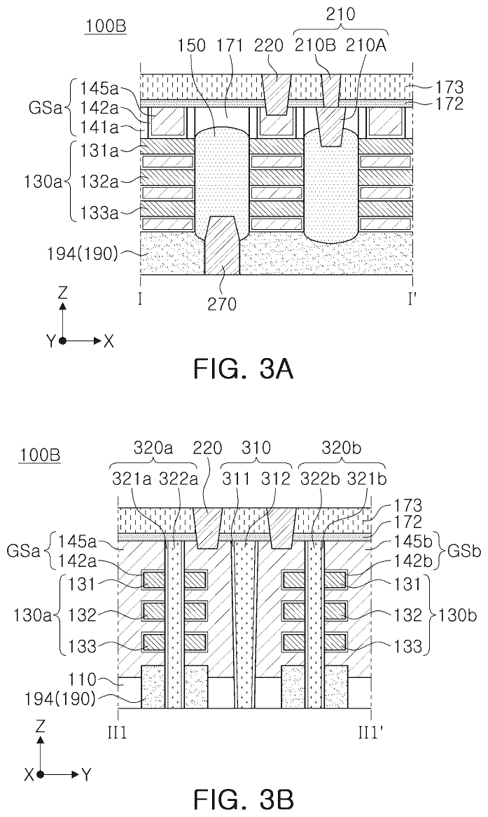

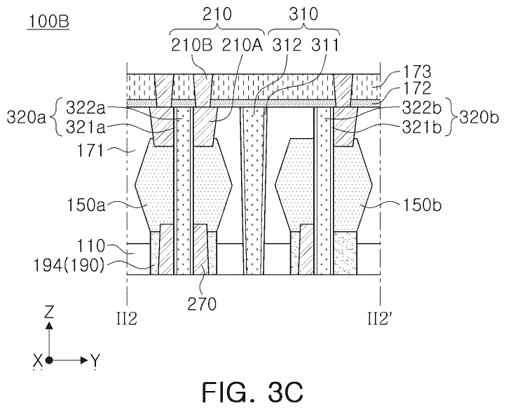

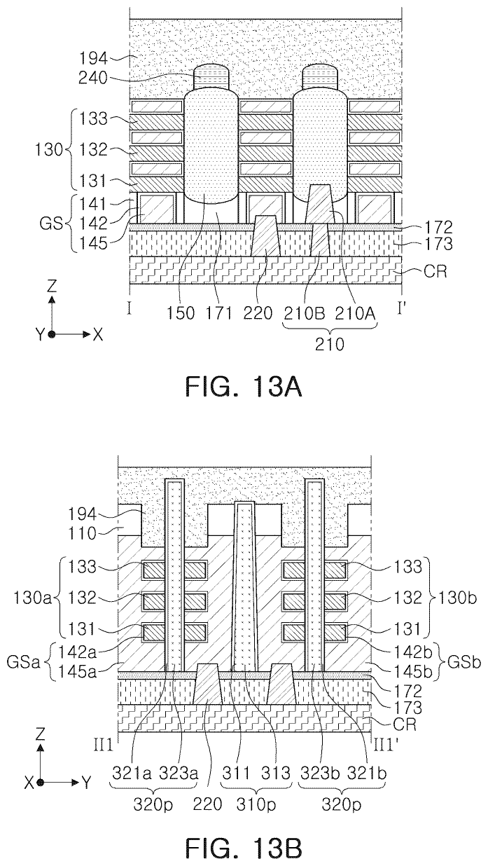

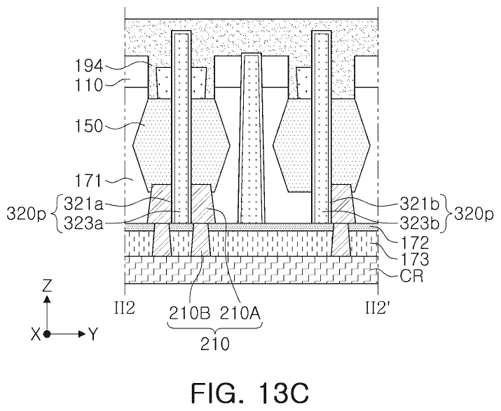

In the present embodiment, the substrate insulating layer 190 may have a (protruding) insulating pattern 194 that extends in a first direction (for example, X-axis direction) and protrudes upwardly (e.g., in a third direction (for example, Z-axis direction)). In some embodiments, the substrate insulating layer 190 may include a first insulating material layer 194 (the protruding insulating pattern 194) and a second insulating material layer 195. The first insulating material layer 194 may correspond to the (protruding) insulating pattern 194 of a fin structure. The first insulating material layer 194 and the second insulating material layer 195 may be formed by different processes (for example, see FIGS. 13A, 13B, 13C, 14A, 14B, 14C, 15A, 15B, 15C, 16A, 16B, 16C, 17A, 17B, and 17C). In some embodiments, the substrate insulating layer 190 may have a single-layer structure (see FIGS. 3A, 3B, and 3C). For example, the substrate insulating layer 190 may consist of the first insulating material layer 194.

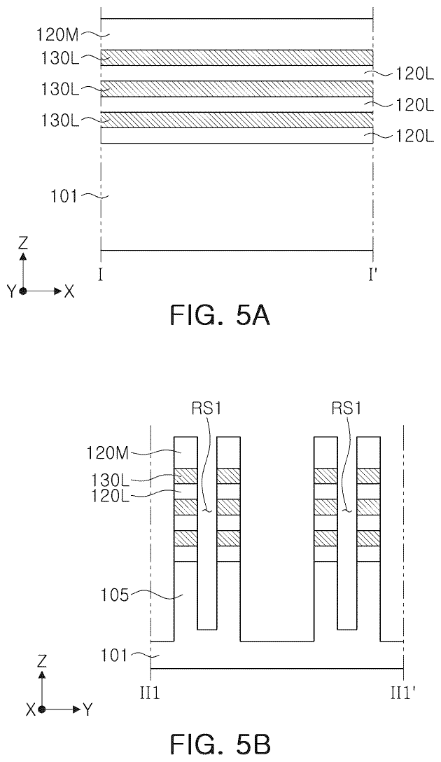

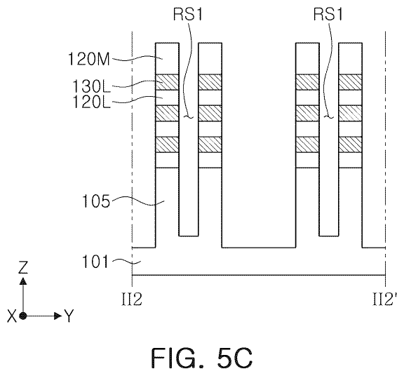

Among the substrate insulating layers 190, the first insulating material layer 194 may be formed by an additional process (for example, see FIGS. 13A, 13B, and 13C) after removing a substrate including a semiconductor material (for example, see substrate 101 of FIGS. 5A, 5B, and 5c) in a series of manufacturing processes of a semiconductor device, or may be a layer formed by oxidizing the substrate. The substrate 101 may be referred to as a semiconductor substrate 101. The first insulating material layer 194 may include an insulating material such as an oxide or a nitride. For example, the first insulating material layer 194 may include Spin-on Hardmask (SOH), Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, and/or combinations thereof. The first insulating material layer 194 may be formed using a chemical vapor deposition (CVD), a flowable-CVD process, and/or a spin coating process. The second insulating material layer 195 may be disposed below the lower surface of the first insulating material layer 194. The second insulating material layer 195 may include, for example, a low-κ material.

The (protruding) insulating pattern 194 of the substrate insulating layer 190 may be understood as a portion corresponding to the fin-shaped active pattern (see 105 of FIGS. 5A, 5B, and 5C) of the semiconductor substrate (see 101 of FIGS. 5A, 5B, and 5C). The insulating pattern 194 may be formed in the process of replacing the semiconductor substrate 101 with the substrate insulating layer 190.

Referring to FIGS. 2B and 2C, the device isolation layer 110 may define (may extend around) the insulating pattern 194 on the substrate insulating layer 190. The device isolation layer 110 may be disposed on the substrate insulating layer 190 to be on (e.g., to cover) both sides (e.g., opposite sides in a second direction (e.g., Y-axis direction)) of the insulating pattern 194. In some embodiments, the device isolation layer 110 may be on (an upper surface of) the second insulating material layer 195 and on (a side surface of) the first insulating material layer 194 of the substrate insulating layer 190. The upper region of the insulating pattern 194 may be exposed from the upper surface of the device isolation layer 110. For example, the upper region (e.g., the upper surface) of the insulating pattern 194 may be higher than the upper surface of the device isolation layer 100. The device isolation layer 110 may define the fin-shaped structure. The device isolation layer 110 may be disposed on the substrate insulating layer 190. The device isolation layer 110 may include, for example, an oxide film, a nitride film, and/or a combination thereof. In some embodiments, the device isolation layer 110 may include a shallow trench isolation (STI) region defining the fin-shaped structure, and a deep trench isolation (DTI) region (not illustrated) formed deeper than the STI. The device isolation layer 110 may be formed such that an upper region of the fin-shaped structure, specifically, an upper region of the fin-shaped active pattern (see 105 of FIGS. 5A, 5B, and 5C), is exposed. In some embodiments, the device isolation layer 110 may have a curved upper surface having a higher level as it approaches the fin-shaped active pattern. Herein, the term “level”, “vertical level”, “height”, or the like may refer to a relative location with respect to a reference element in the third direction (e.g., Z-axis direction). A level, a vertical level, height, or the like may be a distance from the lower surface of the substrate insulating layer 190 in the third direction. For example, a higher level may mean a farther distance from the lower surface of the substrate insulating layer 190 in the third direction, and a lower level may mean a closer distance to the lower surface of the substrate insulating layer 190 in the third direction. Herein, the first direction and the second direction may be parallel with an upper surface of the substrate insulating layer 190. The third direction may be perpendicular to the upper surface of the substrate insulating layer 190.

The first and second gate structures GSa and GSb may extend in a second direction (for example, Y-axis direction) intersecting with (e.g., overlapping in the third direction) the insulating pattern 194 and may be disposed spaced apart from each other in the second direction.

A channel region of transistors may be formed in the first semiconductor patterns 130a intersecting with the first gate electrode 145a of the first gate structure (GSa). The first gate structure (GSa) may include a first gate electrode 145a extending around (e.g., surrounding) the first semiconductor patterns 130a, and a first gate dielectric layer 142a and a first gate spacer layer 141a which may be disposed between the first gate electrode 145a and the respective first semiconductor patterns 130a and between the first gate electrode 145a and the substrate insulating layer 190. In example embodiments, the first gate structure (GSa) may further include a capping layer (not illustrated) on the upper surface of the first gate electrode 145a.

The first gate dielectric layer 142a may be disposed between the (protruding) insulating pattern 194 and the first gate electrode 145a and between the first semiconductor patterns 130a and the first gate electrode 145a, and may be disposed to cover at least a portion of the surfaces of the first gate electrode 145a. For example, the first gate dielectric layers 142a may be disposed to extend around (e.g., surround) all surfaces except the uppermost surface of the first gate electrode 145a. For example, the first gate dielectric layers 142a may be on the lower surface and side surfaces of the first gate electrode 145a. The first gate dielectric layers 142a may extend between the first gate electrode 145a and the first gate spacer layers 141a, but are not limited thereto. The first gate dielectric layer 142a may include, for example, an oxide, a nitride, and/or a high-k material. The high-k material may mean a dielectric material having a higher dielectric constant than a silicon oxide film (SiO₂). The high-k material may be, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃). According to example embodiments, the first gate dielectric layer 142a may be formed of a multilayer structure.

The first gate electrode 145a may include a conductive material, for example, a metal nitride such as a titanium nitride (TiN), a tantalum nitride (TaN), and/or a tungsten nitride (WN), a metal material such as aluminum (Al), tungsten (W), and/or molybdenum (Mo), and/or a semiconductor material such as doped polysilicon. According to example embodiments, the first gate electrode 145a may be formed of a multilayer structure. In an area not illustrated, the first gate electrodes 145a may be (electrically) connected to upper contact plugs disposed thereon.

The first gate electrode 145a may be separated into a plurality of regions by the second separation pattern 320a. The plurality of regions of the first gate electrode 145a may be electrically insulated (e.g., electrically separated) from each other by the second separation pattern 320a, and the plurality of regions of the first gate electrode 145a may respectively configure to be (a portion of) an nFET and (a portion of) a pFET. In some embodiments, the plurality of regions of the first gate electrode 145a may configure nFETs having different operating voltages, or may configure pFETs having different operating voltages.

The first gate spacer layers 141a may be disposed on both sides (e.g., opposite sides in the first direction) of the first gate electrode 145a on the first semiconductor patterns 130a. The first gate spacer layers 141a may insulate the source/drain regions 150 and the first gate electrodes 145a. For example, the first gate spacer layers 141a may (electrically) separate the source/drain regions 150 from the first gate electrodes 145a. According to example embodiments, the shape of the top (e.g., upper end or upper surface) of the first gate spacer layers 141a may be variously changed, and the first gate spacer layers 141a may be formed of a multilayer structure. The first gate spacer layers 141a may include, for example, an oxide, a nitride, and/or an oxynitride. The first gate spacer layers 141a may be formed of, for example, a low-κ film.

The second gate structure (GSb) may include a second gate electrode 145b, a second gate dielectric layer 142b, and a second gate spacer layer 141b. The second gate structure (GSb) may have the same or similar characteristics as the first gate structure (GSa), and the description of the second gate structure (GSb) may be replaced with the description of the first gate structure (GSa) described above.

The semiconductor patterns 130 may include first semiconductor patterns 130a and second semiconductor patterns 130b. The first semiconductor patterns 130a and the second semiconductor patterns 130b may be stacked to be spaced apart from each other in a third direction (for example, Z-axis direction), and may be disposed to be surrounded by the first and second gate structures GSa and GSb, respectively.

The semiconductor patterns 130 may be disposed on the (protruding) insulating pattern 194, to intersect with the first and second gate structures GSa and GSb. The semiconductor patterns 130 may include a plurality of layers spaced apart from each other in a direction (e.g., the third direction) perpendicular to the upper surface of the (protruding) insulating pattern 194, which may be sequentially referred to as first, second, and third channel layers 131, 132 and 133 from the top (e.g., upper end of the semiconductor patterns 130). The semiconductor patterns 130 may be (electrically) connected to the source/drain regions 150. Each of the first and second semiconductor patterns 130a and 130b may have a width that is the same as or similar to the width of the first gate structure GSa or the second gate structure GSb in the first direction (for example, the X-axis direction).

The semiconductor patterns 130 may include (e.g., may be made of) a semiconductor material, and may include, for example, silicon (Si), silicon germanium (SiGe), and/or germanium (Ge). The semiconductor patterns 130 may be may include (e.g., made of) the same material as the semiconductor substrate (see 101 of FIGS. 5A, 5B, and 5C). The number and shape of the channel layers may be varied in various embodiments.

In the semiconductor device 100A, the gate electrode 145 (e.g., the first gate electrode 145a and/or the second gate electrode 145b) may be disposed between the respective semiconductor patterns 130 and on the semiconductor patterns 130. Accordingly, the semiconductor device 100A may include a transistor having a Multi Bridge Channel FET (MBCFET™) structure, which is a gate-all-around type field effect transistor.

The source/drain regions 150 may be disposed on the (protruding) insulating pattern 194 of the substrate insulating layer 190 and may include first and second source/drain regions 150a, 150b) respectively (electrically) connected to the first side surfaces (for example, X-axis direction) of the first and second semiconductor patterns 130a and 130b.

The source/drain regions 150 may be disposed on the (protruding) insulating pattern 194 on both sides (e.g., opposite sides in the first direction) of the gate structures (GS) and may be respectively disposed to contact the semiconductor patterns 130. The source/drain regions 150 may be connected to the first side surfaces (for example, X-axis direction) of the semiconductor patterns 130. The source/drain regions 150 may be provided as a source region or a drain region of the transistor. The source/drain regions 150 may be disposed spaced apart from each other in a first direction (for example, X-axis direction) by a gate structure (GS). The source/drain regions 150 may be (electrically) connected to a backside contact plug 270A through a lower surface or bottom thereof. A lower region of the source/drain region 150 may have a recessed shape by the backside contact structure 270. For example, the backside contact structure 270 may extend into (penetrate) a lower region of the source/drain region 150 (in the third direction). The source/drain region 150 may be electrically connected to a power delivery structure through the backside contact structure 270 (e.g., a first portion 270A and/or a second portion 270B of the backside contact structure 270) to receive power. The upper surface of the source/drain regions 150 may be located at the same or similar height as the lower surface of the gate electrode 145 (e.g., a lower surface of an upper portion of the gate electrode 145) on the semiconductor patterns 130, and the height may be variously changed in embodiments. In some embodiments, the upper surface of the source/drain region 150 may be at the same or similar height as the upper surface of the uppermost semiconductor pattern 130 (e.g., the upper surface of the first channel layer 131).

The source/drain regions 150 may include, for example, a semiconductor material, such as silicon (Si) and/or germanium (Ge). The source/drain regions 150 may include epitaxial layers composed of multiple layers, and the above-described multiple epitaxial layers may have different compositions. For example, the concentrations of non-silicon elements of the multiple epitaxial layers may be different from each other. The non-silicon elements may be, for example, germanium (Ge) and/or doping elements.

The source/drain regions 150 may further include impurities. When the semiconductor device 100A is a pFET, the impurities may be boron (B), gallium (Ga), and/or indium (In), and when the semiconductor device 100A is an nFET, the impurities may be phosphorus (P), arsenic (As), and/or antimony (Sb). According to example embodiments, the source/drain regions 150 may include multiple regions including different concentrations of elements and/or doping elements. The source/drain region 150 may have a cross-section in the second direction (for example, Y-axis direction) of a circular, elliptical, pentagonal, hexagonal or similar shape. However, in embodiments, the source/drain region 150 may have various shapes, for example, may have any one of a polygonal, circular, and rectangular shape.

The first separation pattern 310 extends in a third direction (for example, the Z-axis direction) perpendicular to the upper surface of the substrate insulating layer 190 between the first and second gate structures GSa and GSb and may insulate (e.g., electrically separate) the first and second gate structures GSa and GSb, specifically, the first and second gate electrodes 145a and 145b, from each other. The first separation pattern 310 may extend in the first direction (for example, the X-axis direction) on the substrate insulating layer 190, and the first separation pattern 310 may extend parallel to the first and second gate structures GSa and GSb. The first separation pattern 310 may serve to insulate electrical signals between transistors. The first separation pattern 310 may extend in (e.g., penetrate) at least a portion of the device isolation layer 110 in the third direction (for example, the Z-axis direction). The lower surface of the first separation pattern 310 may be located at the same level as the lower surface of the device isolation layer 110, but is not limited thereto.

The first separation pattern 310 may include a first air gap AG1 on the inner side of the first separation pattern 310 and a first insulating liner 311 having a continuously extending side surface and defining the first air gap AG1. The first air gap AG1 may be within the first separation pattern 310. For example, a side surface (e.g., an inner side surface) of the first insulating liner 311 may define at least a portion of the boundary of the first air gap AG1.

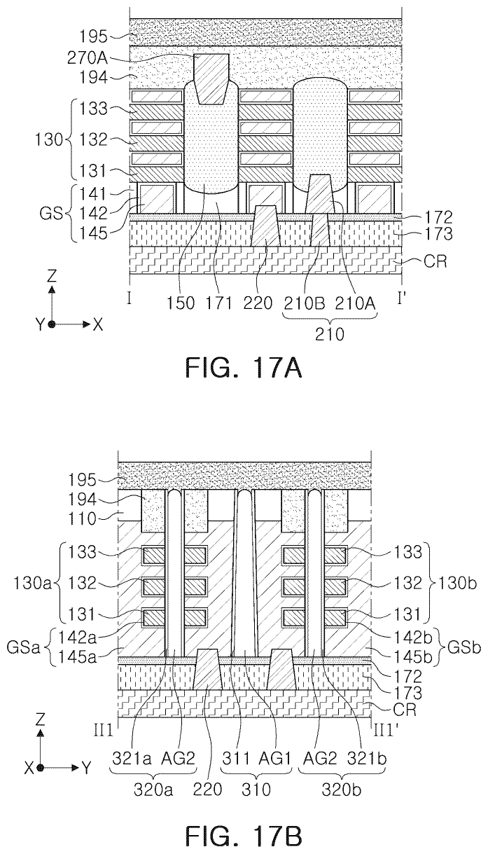

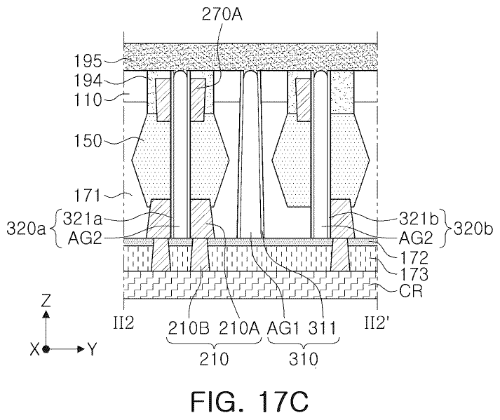

The first air gap AG1 may be an internal space of the first separation pattern 310 defined by the first insulating liner 311. The first air gap AG1 may be a space sealed by the first insulating liner 311. The upper end of the first air gap AG1 may be located at the same level as the upper end of the first insulating liner 311, and may be located at the same level as the lower end of the second interlayer insulating layer 172, but is not limited thereto. The lower portion of the first air gap AG1 may have a convex shape downward (toward the lower surface of the substrate insulating layer 190 in the third direction). The shape of the lower portion of the first air gap AG1 may be variously modified depending on the method of the process of closing the first air gap AG1 (see process operations of FIGS. 17A, 17B, and 17C). The lower end of the first air gap AG1 may be located at the same level as the lower end (e.g., the lower surface) of the device isolation layer 110 and the lower end (e.g., the lower surface) of the (protruding) insulating pattern 194, but is not limited thereto. The volume of the first air gap AG1 may be modified depending on the thickness of the first insulating liner 311. For example, the greater the thickness of the first insulating liner 311 is, the less (smaller) the volume of the first air gap AG1 may be, and the smaller the thickness of the first insulating liner 311 is, the greater (larger) the volume of the first air gap AG1 may be. The first air gap AG1 may include air, and a second insulating material layer 195 may be disposed under the first air gap AG1. In some embodiments, the first insulating liner 311, the second insulating material layer 195, and the second interlayer insulating layer 172 may extend around (may define) the first air gap AG1. The side (e.g., side edge, circumference, or perimeter) of the first air gap AG1 may be (may be defined by, may be in contact with, or may expose) the (inner) side surface of the first insulating liner 311. The upper end of the first air gap AG1 may be (may be defined by, may be in contact with, or may expose) the lower surface of the second interlayer insulating layer 172. The lower end of the first air gap AG1 may be (may be defined by, may be in contact with, or may expose) the upper surface of the second insulating material layer 195.

The first insulating liner 311 may form an outer wall of the first separation pattern 310 and define the first air gap AG1. The first insulating liner 311 may have a continuous side along the outer wall of the first separation pattern 310, and specifically, the first insulating liner 311 may have a structure that does not have a step difference. The structure of the first insulating liner 311 described above may be according to the first separation pattern 310 whose width in the horizontal direction continuously changes. The first separation pattern 310 may have a tapered shape whose width decreases toward (the lower surface of) the substrate insulating layer 190, and the width may continuously decrease, but is not limited thereto. In an example, the first separation pattern 310 may have a structure having a constant width in the horizontal direction (e.g., in the first direction and/or the second direction).

The first insulating liner 311 may respectively be in contact with at least portions of the device isolation layer 110, the first interlayer insulating layer 171, the second interlayer insulating layer 172, and the first and second gate electrodes 145a and 145b. The first insulating liner 311 may include an insulating material such as silicon nitride, silicon oxide, and/or silicon oxynitride. For example, the first insulating liner 311 may include SiN, SiO₂, and/or SiOCN. The first insulating liner 311 may include, for example, an oxide, but is not limited thereto. In an example, the first insulating liner 311 may include a material having a different selectivity from silicon nitride.

The second separation pattern 320 may extend in (e.g., penetrate) respective at least portions of the first semiconductor patterns 130a and the second semiconductor patterns 130b, on the substrate insulating layer 190 (e.g., on the second insulating material layer 195) in a third direction (for example, the Z-axis direction). The second separation pattern 320 may respectively extend in (e.g., penetrate at least portions of) the first gate electrode 145a and the second gate electrode 145b and may separate each of the first gate electrode 145a and the second gate electrode 145b into a plurality of regions. For example, the second separation pattern 320 extending in the first gate electrode 145a and the first semiconductor pattern 130a may be referred to as the second separation pattern 320a, and the second separation pattern 320 extending in the second gate electrode 145b and the second semiconductor pattern 130b may be referred to as the second separation pattern 320b. An upper surface of the second separation pattern 320 may be (substantially) coplanar with the upper surfaces of the first and second gate electrodes 145a and 145b. The upper surface of the second separation pattern 320 may be covered with a second interlayer insulating layer 172. The second interlayer insulating layer 172 may be on (the upper surface of) the second separation pattern 320. The side surfaces of the second separation pattern 320 may be perpendicular to or inclined to the upper surface of the substrate insulating layer 190 (e.g., the second insulating material layer 195). In example embodiments, the second separation pattern 320 may have a constant width in the first direction and/or the second direction, but is not limited thereto, and may have a tapered shape as it approaches toward the lower surface of the substrate insulating layer 190 in the third direction.

The second separation patterns 320a and 320b may include a second air gap AG2 within each of the second separation patterns 320a and 320b, and second insulating liners 321a and 321b having a side surface extending continuously and defining the second air gap AG2. The second separation pattern 320a may include the second insulating liner 321a extending around (e.g., at least partially defining) the second air gap AG2 in the second separation pattern 320a. Since the second air gap AG2 and the second insulating liners 321a and 321b have the same or similar characteristics as those of the first air gap AG1 and the first insulating liner 311, respectively, the description related to the second air gap AG2 and the second insulating liners 321a and 321b may be replaced with the description related to the first air gap AG1 and the first insulating liner 311. For example, a side surface (e.g., an inner side surface) of the second insulating liner 321 may define at least a portion of the boundary of the second air gap AG2. The first and second separation patterns 310 and 320 may extend parallel to each other in the first direction (for example, the X-axis direction). The first and second separation patterns 310 and 320 may be disposed to be spaced apart from each other in the second direction (for example, the Y-axis direction). Respective upper surfaces of the first and second separation patterns 310 and 320 may be (substantially) coplanar with the upper surface of the first gate electrode 145a and the upper surface of the second gate electrode 145b.

In example embodiments, in the semiconductor device 100A, by forming the first and second separation patterns 310 and 320 including a low dielectric constant material during the backside process for forming the backside contact structure 270, the parasitic voltage problem within the semiconductor device may be improved (e.g., reduced), and accordingly, a semiconductor device with improved reliability and electrical characteristics may be provided.

The backside contact structure 270 may extend in (e.g., may penetrate through) the substrate insulating layer 190 and be (electrically) connected to at least a portion of the source/drain regions 150. The backside contact structure 270 may include a backside contact plug 270A (electrically) connected to the source/drain regions 150 and a backside contact via 270B disposed below the backside contact plug 270A. The backside contact plug 270A may include a plurality of portions contacting both side surfaces (e.g., opposite side surface in the second direction) of the second separation pattern 320 in the second direction (for example, the Y-axis direction), and the plurality of portions may be electrically insulated (e.g., electrically separated from each other) by the second separation pattern 320. The backside contact plug 270A and the backside contact via 270B may be referred to as a first portion 270A and a second portion 270B of the backside contact structure 270, respectively. The first portion 270A may extend into (e.g., penetrate) at least a portion of (the lower surface or the lower portion of) the source/drain region 150. The second portion 270B may extend into (e.g., penetrate) at least a portion of the second insulating material layer 195, and the level of the upper end of the second portion 270B may be located at a level higher than the lower end (the lower surface) of the first insulating material layer 194 or the upper end (the upper surface) of the second insulating material layer 195.

The first interlayer insulating layer 171 may be on (may be disposed to cover) the source/drain regions 150, the gate structure (GS), and the device isolation layer 110. The first interlayer insulating layer 171 may include for example, an oxide, a nitride, an oxynitride, and/or a low-κ dielectric.

The second and third interlayer insulating layers 172 and 173 may be disposed on the upper surfaces of the first and second gate electrodes 145a and 145b. The second interlayer insulating layer 172 may be referred to as a buffer insulating layer and may include, but is not limited to, an oxide. The second interlayer insulating layer 172 may include a material having a different selectivity from silicon nitride.

The frontside contact structure 210 may extend in (e.g., penetrate) at least a portion of (the upper surface or the upper portion of) at least one of the source/drain regions 150 and may be (electrically) connected to the at least one source/drain region 150. The frontside contact structure 210 may include a frontside contact plug 210A that extends into (e.g., penetrates) at least portions of the first interlayer insulating layer 171 and the source/drain region 150 and is (electrically) connected to the source/drain region 150, and a frontside contact via 210B that is disposed on the frontside contact plug 210A and extends in (e.g., penetrates) at least portions of the second and third interlayer insulating layers 172 and 173. The frontside contact structure 210 may have similar characteristics to the backside contact structure 270.

The gate contact 220 may extend in (e.g., penetrate) at least portions of the second and third interlayer insulating layers 172 and 173 and may respectively be (electrically) connected to the first and second gate electrodes 145a and 145b. The gate contact 220 may have similar features to the frontside and backside contact structures 210 and 270.

FIG. 3A is a cross-sectional view of a semiconductor device 100B according to example embodiments taken along line I-I′ corresponding to line I-I′ of the semiconductor device 100A of FIGS. 1 and 2A, FIG. 3B is a cross-sectional view of a semiconductor device 100B according to example embodiments taken along line II1-II1′ corresponding to line II1-II1′ of the semiconductor device 100A of FIGS. 1 and 2B, and FIG. 3C is a cross-sectional view of a semiconductor device 100B according to example embodiments taken along line II2-II2′ corresponding to line II2-II2′ of the semiconductor device 100A of FIGS. 1 and 2C.

Referring to FIGS. 3A, 3B, and 3C, a semiconductor device 100B of example embodiments may have features identical to or similar to those described with reference to FIGS. 1, 2A, 2B, and 2C, except that it includes first and second separation insulating layers 312 and 322 in which first and second separation patterns 310 and 320 are disposed on the inside, respectively, and that the substrate insulating layer 190 is a single layer. The first and second separation patterns 310 and 320 (e.g., the first and second separation insulating layers 312 and 322) of the semiconductor device 100B may include a low-κ dielectric material, for example, a material having a lower dielectric constant than silicon nitride (SiN). In some embodiments, the substrate insulating layer 190 may be a single layer made of a single material. The semiconductor device 100B may reduce parasitic voltage within the semiconductor device by introducing a structure in which the first and second separation patterns 310 and 320 separating the gate structure include a low-κ dielectric material, and may further improve the electrical characteristics of the semiconductor device.

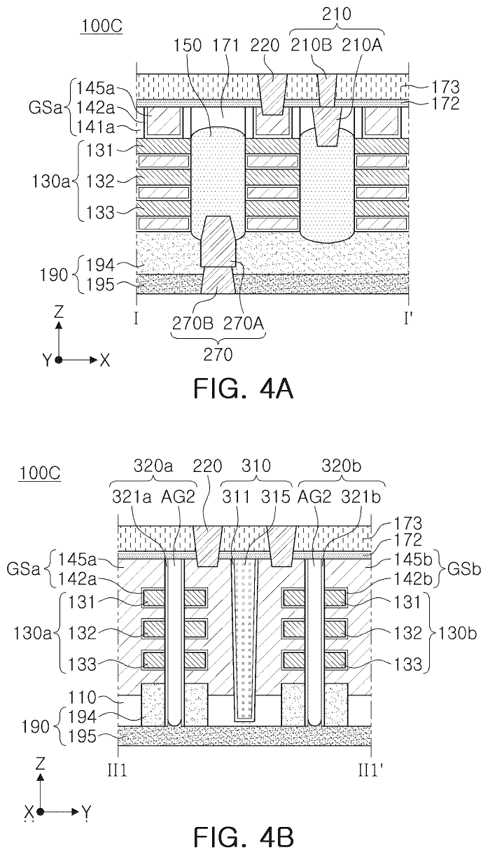

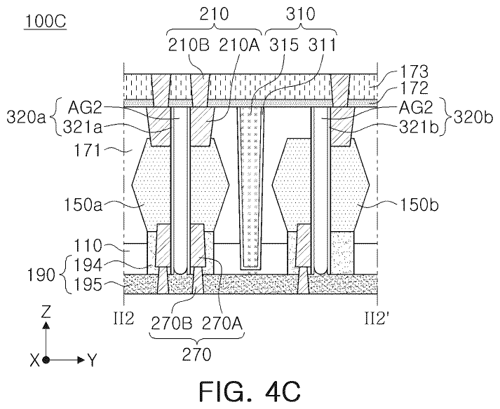

FIG. 4A is a cross-sectional view of a semiconductor device 100C of example embodiments taken along line I-I′ corresponding to line I-I′ of the semiconductor device 100A of FIGS. 1 and 2A, FIG. 4B is a cross-sectional view of a semiconductor device 100C of example embodiments taken along line II1-II1′ corresponding to line II1-II1′ of the semiconductor device 100A of FIGS. 1 and 2B, and FIG. 4C is a cross-sectional view of a semiconductor device 100C of example embodiments taken along line II2-II2′ corresponding to line II2-II2′ of the semiconductor device 100A of FIGS. 1 and 2C.

Referring to FIGS. 4A, 4B, and 4C, the semiconductor device 100C of example embodiments may have features that are the same as or similar to those described with reference to FIGS. 1, 2A, 2B, 2C, 3A, 3B, and 3C, except that the lengths (in the third direction) of the first and second separation patterns 310 and 320 are different and different materials are included in the first and second separation patterns 310 and 320. The semiconductor device 100C may include a plurality of separation patterns extending in (e.g., penetrating) at least a portion of the first and second gate structures GSa and GSb, including a first separation pattern 310 having a first length (in the third direction), and a second separation pattern 320 having a second length (in the third direction) equal to or greater than the first length.

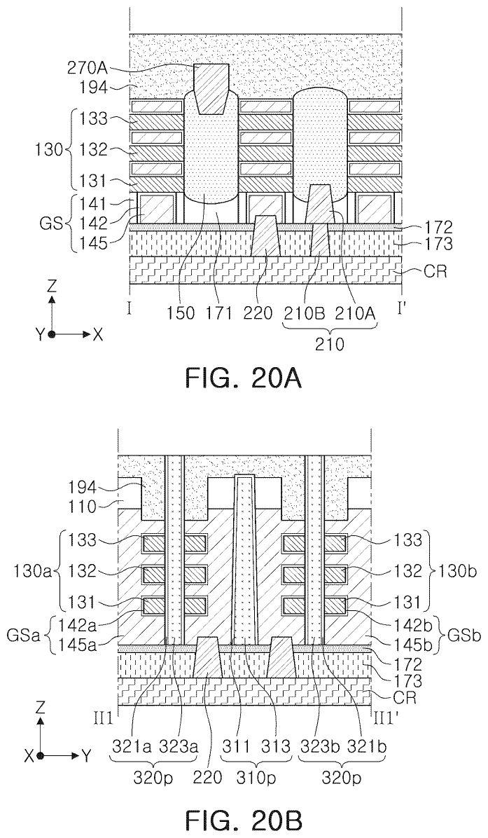

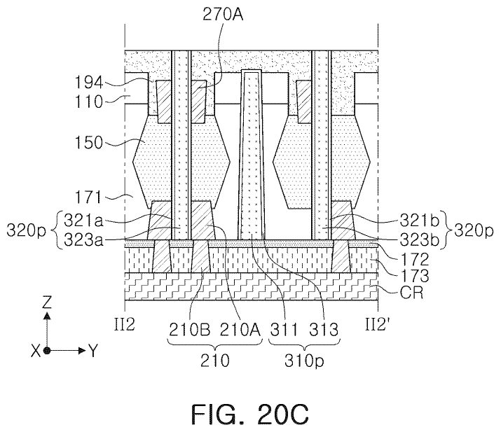

The first separation pattern 310 may include a first insulating liner 311 forming (constituting) an outer wall (e.g., a lower wall and/or sidewalls), and a first separation insulating layer 315 (at least partially) filling an inner side of the first insulating liner 311. The first separation insulating layer 315 may include, for example, silicon nitride, but is not limited thereto. The first insulating liner 311 may include a material having a different selectivity from the first separation insulating layer 315, and may include an oxide, but is not limited thereto. The second separation pattern 320 may include an air gap AG2 (at least partially) defined by the second insulating liner 321 forming an outer wall (e.g., a lower wall and/or sidewalls) and the second insulating liner 321. The second insulating liner 321 may have the same or similar characteristics as the first insulating liner 311. In some embodiments, the second separation pattern 320 may include a low-κ dielectric material instead of the air gap AG2, and the second separation pattern 320 having a second length (in the third direction) greater (longer) than the first length may include a material having a lower dielectric constant than the first separation pattern 310 on (in) the inner side. The semiconductor device 100C may select separation patterns (e.g., the first and second separation patterns 310 and 320) having exposed bottoms (lower end or lower surface) according to the length during the process (see FIGS. 20A, 20B, and 20C), and selectively apply the area to which the separation patterns according to example embodiments are applied by replacing the insulating material forming the interior of the separation patterns having exposed bottoms with an air gap or a low-κ dielectric material having a low dielectric constant.

FIGS. 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, and 12C are cross-sectional views for explaining some processes (gate structure and preliminary separation pattern forming processes) of a method of manufacturing a semiconductor device 100A according to example embodiments, and FIGS. 13A, 13B, 13C, 14A, 14B, 14C, 15A, 15B, 15C, 16A, 16B, 16C, 17A, 17B, and 17C are cross-sectional views for explaining other some processes (backside contact plug and air gap forming processes) of a method of manufacturing a semiconductor device according to example embodiments. Specifically, FIGS. 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, and 12C are cross-sectional views for explaining a front-side process, and FIGS. 13A, 13B, 13C, 14A, 14B, 14C, 15A, 15B, 15C, 16A, 16B, 16C, 17A, 17B, and 17C are cross-sectional views for explaining a back-side process. FIGS. 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, and 17C illustrate cross sections corresponding to FIGS. 2A, 2B, and 2C.

Referring to FIGS. 5A, 5B, and 5C, a stacked structure may be formed by alternately stacking sacrificial layers 120L and semiconductor layers 130L on a substrate 101, and a portion of the stacked structure may be removed to form a fin-shaped active structure, and a first recessed region RSI extending in (e.g., penetrating) a portion of the fin-shaped active structure may be formed.

The substrate 101 may include, for example, silicon (Si), germanium (Ge), and/or silicon germanium (SiGe). The substrate 101 may include a bulk wafer, an epitaxial layer, a silicon on insulator (SOI) layer, or a semiconductor on insulator (SeOI) layer.

The sacrificial layers 120L may be layers that are replaced with gate dielectric layers 142 and gate electrodes 145 below an uppermost semiconductor pattern 130 among the semiconductor patterns 130, as illustrated in FIG. 2A, through a subsequent process. The sacrificial layers 120L may be formed of (may include) a material having etching selectivity with respect to the semiconductor layers 130L. The semiconductor layers 130L may include a different material from the sacrificial layers 120L. The sacrificial layers 120L and the semiconductor layers 130L may include a semiconductor material, such as, silicon (Si), silicon germanium (SiGe), and germanium (Ge), but may include different materials, and may or may not include impurities. For example, the sacrificial layers 120L may include silicon germanium (SiGe), and the semiconductor layers 130L may include silicon (Si). The sacrificial layers 120L and the semiconductor layers 130L may be formed by performing an epitaxial growth process from a substrate (the substrate 101). The number of layers of the semiconductor layers 130L alternately stacked with the sacrificial layers 120L is illustrated as three in FIGS. 5A, 5B, and 5C, but may be variously changed in embodiments.

The fin-shaped active structure may be formed in a line shape extending in a first direction (for example, X-axis direction) and may be formed spaced apart from an adjacent fin-shaped active structure in a second direction (for example, Y-axis direction) intersecting the first direction. The side surfaces of (the sub-elements of) the fin-shaped active structure in the second direction may be (substantially) coplanar with each other and may be positioned on a straight line.

A first recessed region RSI may be formed by removing a portion of the fin-shaped active structure (e.g., a portion of each of the fin-shaped active pattern 105, the sacrificial layers 120L, and the semiconductor layers 130L). The first recessed region RSI may correspond to a region for forming a second separation pattern 320 in a subsequent process, and a lowermost end of the first recessed region RSI may be located at the same level as the lowermost end of the second separation patterns 320 (the second separation patterns 320a and 320b).

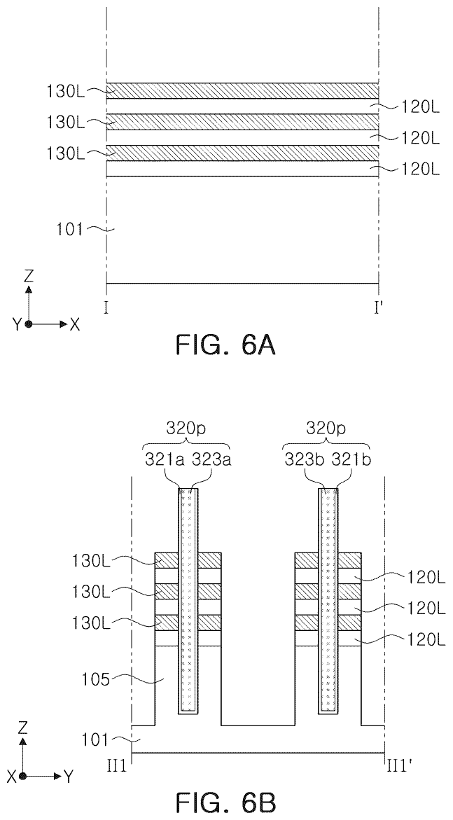

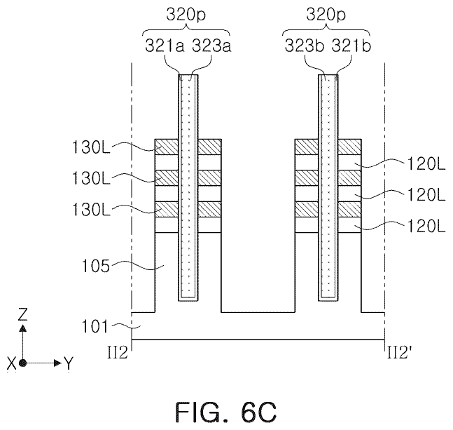

Referring to FIGS. 6A, 6B, and 6C, a preliminary second separation pattern 320p may be formed, and the uppermost sacrificial layer 120M may be removed.

The preliminary second separation pattern 320p may include a second insulating liners 321a and 321b conformally formed along the first recessed region (see RS1 of FIGS. 5A, 5B, and 5C) and second separation insulating layers 323a and 323b (at least partially) filling the inner side of the second insulating liners 321a and 321b. The second insulating liners 321a and 321b may include a material having a different selectivity from the second separating insulating layers 323a and 323b. In an example, the second insulating liners 321a and 321b may include an oxide, and the second separating insulating layers 323a and 323b may include silicon nitride, but is not limited thereto. The height of the preliminary second separation pattern 320p may be determined according to the height of the uppermost sacrificial layer 120M disposed on the upper surface of the uppermost semiconductor layer 130L, and after the formation process of the preliminary second separation pattern 320p, the uppermost sacrificial layer 120M may be removed.

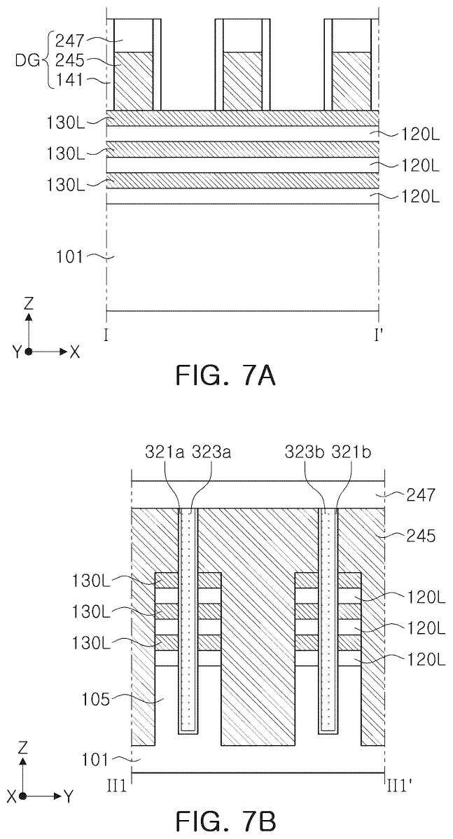

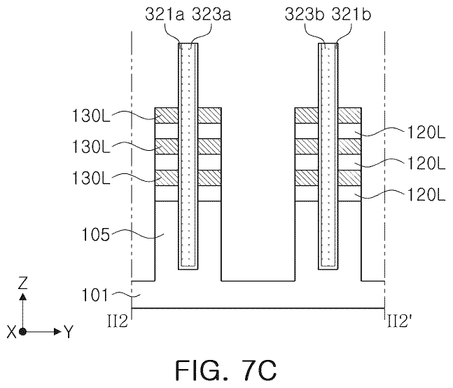

Referring to FIGS. 7A to 7C, a sacrificial gate structure (DG) and gate spacers 141 may be formed on the substrate 101 (e.g., on the fin-shaped active structure).

The sacrificial gate structure (DG) may be a sacrificial structure formed in an area where a gate dielectric layer 142 and a gate electrode 145 are disposed on the semiconductor patterns 130 through a subsequent process, as illustrated in FIG. 2. The sacrificial gate structure (DG) may have a line shape extending in one direction while intersecting with the fin-shaped active structure. The sacrificial gate structures (DG) may be disposed, for example, to extend in a second direction (for example, Y-axis direction) and spaced apart from each other in a first direction (for example, X-axis direction).

The sacrificial gate structure (DG) may include a sacrificial gate layer 245 and a mask pattern 247, which are sequentially stacked. The sacrificial gate layer 245 may be patterned using the mask pattern 247. For example, the sacrificial gate layer 245 may include polysilicon. The sacrificial gate layer 245 may also be formed of a plurality of layers. The mask pattern 247 may include, for example, silicon oxide and/or silicon nitride. Gate spacers 141 may be formed on both (opposite in the first direction) sidewalls of the dummy gate structures (DG). The gate spacers 141 may include (e.g., may be made of) a low-κ material as described above, and may include, for example, SiO, SiN, SiCN, SiOC, SiON, and/or SiOCN. The upper surface of the sacrificial gate layer 245 may be (substantially) coplanar with the upper surface of the preliminary second separation pattern 320p, and the mask pattern 247 may be formed on the sacrificial gate layer 245 and the preliminary second separation pattern 320p.

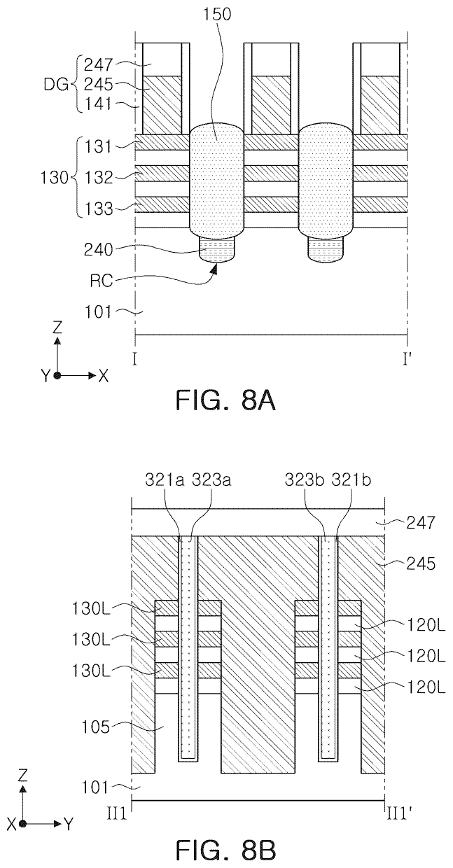

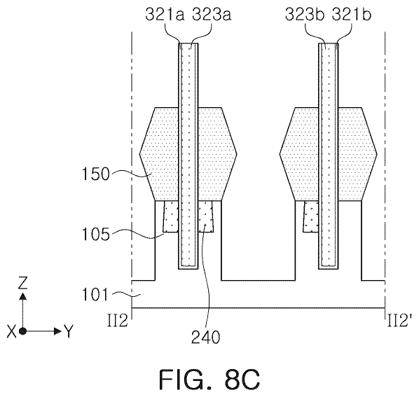

Referring to FIGS. 8A, 8B, and 8C, the sacrificial layers 120L and semiconductor layers 130L exposed from the sacrificial gate structures (DG) may be partially removed to form recessed regions, and vertical sacrificial patterns 240 and source/drain regions 150 may be formed on (in) the recessed regions.

Using the sacrificial gate structures (DG) and gate spacers 141 as masks, the exposed sacrificial layers 120L and semiconductor layers 130L may be partially removed to form recessed regions (RC). As a result, the semiconductor patterns 130 may form channel structures (e.g., first, second, and third channel layers 131, 132 and 133) having a limited length in the first direction (for example, X-axis direction).

The sacrificial layers 120L may be selectively etched with respect to the channel structures by, for example, a wet etching process, and removed from the side surface in the first direction to a predetermined depth. The sacrificial layers 120L may have concave side surfaces inwardly by the side etching as described above.

The lower surface of the vertical sacrificial pattern 240 may be defined by the depth of the recessed regions (RC). The lower surface of the vertical sacrificial pattern 240 may have a lower level than the lower surface of the fin-shaped active pattern 105, for example, the lower surface of the device isolation layer 110, but is not limited thereto. The vertical sacrificial pattern 240 may include a material having a selectivity with respect to the material of the substrate 101. For example, the substrate 101 may be silicon, and the vertical sacrificial pattern 240 may be silicon germanium (SiGe). In some embodiments, the vertical sacrificial pattern 240 may further include impurities. The vertical sacrificial pattern 240 may include a high concentration of impurities, and the impurities may include elements such as boron (B) and/or carbon (C). In example embodiments, the vertical sacrificial pattern 240 may include an insulating material such as SiO, SiN, SiCN, SiOC, SiON, and SiOCN, but is not limited thereto. The vertical sacrificial pattern 240 may correspond to a contact align element for the backside contact structure 270.

The source/drain regions 150 may be formed by growing from the upper surface of the fin-shaped active pattern 105 and the side surfaces of the semiconductor patterns 130, for example, by a selective epitaxial process. The source/drain regions 150 may include a plurality of epitaxial layers, and the plurality of epitaxial layers may include impurities by in-situ doping and may have different compositions and/or doping concentrations.

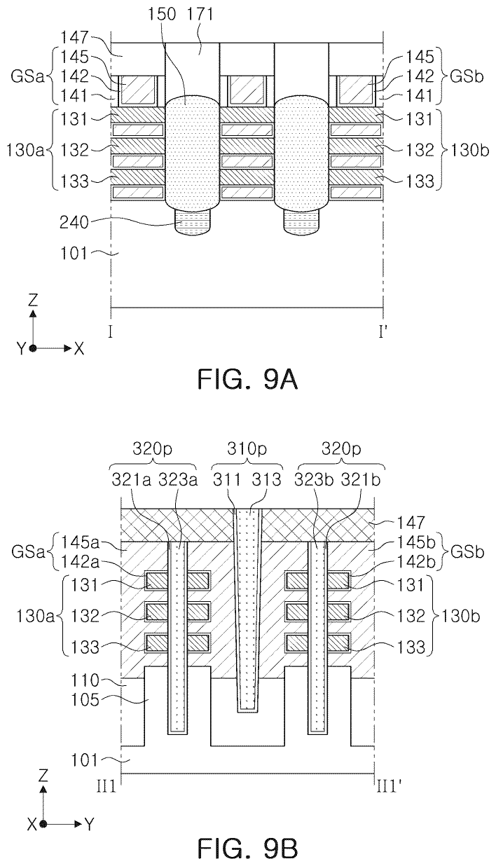

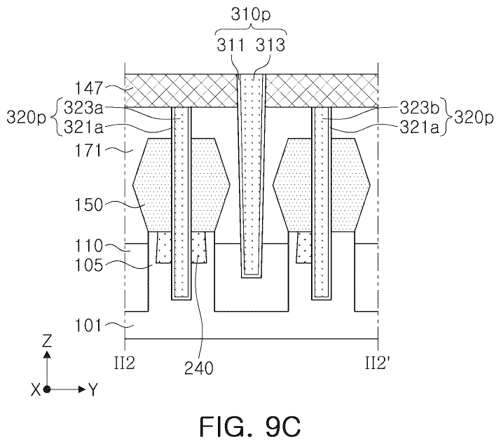

Referring to FIGS. 9A, 9B, and 9C, the sacrificial gate structure (DG) and the sacrificial layers 120L may be removed, gate dielectric layers 142 and gate electrodes 145 may be formed to form gate structures (GS), and a preliminary first separation pattern 310p extending parallel to the gate structures (GS) may be formed.

The first interlayer insulating layer 171 may be formed by forming an insulating film covering the sacrificial gate structures (DG) and source/drain regions 150 and performing a planarization process.

The sacrificial gate structures (DG) and the sacrificial layers 120L may be selectively removed with respect to the gate spacers 141, the first interlayer insulating layer 171, and the semiconductor layers 130L. First, the sacrificial gate structures (DG) are removed to form upper gap regions, and then the sacrificial layers 120L exposed through the upper gap regions are removed to form lower gap regions. In a subsequent process, first and second gate dielectric layers 142a and 142b conformally covering the gap regions and first and second gate electrodes 145a and 145b (at least partially) filling the remaining space are sequentially formed to form gate structures GSa and GSb.

For example, when the sacrificial layers 120L include silicon germanium (SiGe) and the semiconductor layers 130L include silicon (Si), the sacrificial layers 120L may be selectively removed with respect to the semiconductor layers 130L by performing a wet etching process.

The gate capping layer 147 may be formed in the removed region of the first and second gate electrodes 145a and 145b after etching back a portion of the first and second gate electrodes 145a and 145b.

The preliminary first separation pattern 310p may be formed extending in (e.g., penetrating at least a portion of) the gate capping layer 147 and has similar characteristics to the preliminary second separation pattern 320p, so the description related to the preliminary first separation pattern 310p may be replaced with the description related to the preliminary second separation pattern 320p described above. The preliminary first separation pattern 310p may be disposed between the first gate electrode 145a and the second gate electrode 145b and may electrically insulate the first gate electrode 145a and the second gate electrode 145b. The lower end of the preliminary first separation pattern 310p may be located at a level higher than the lower end of the device isolation layer 110, and may be located at a level higher than the lower end of the preliminary second separation pattern 320p, but is not limited thereto.

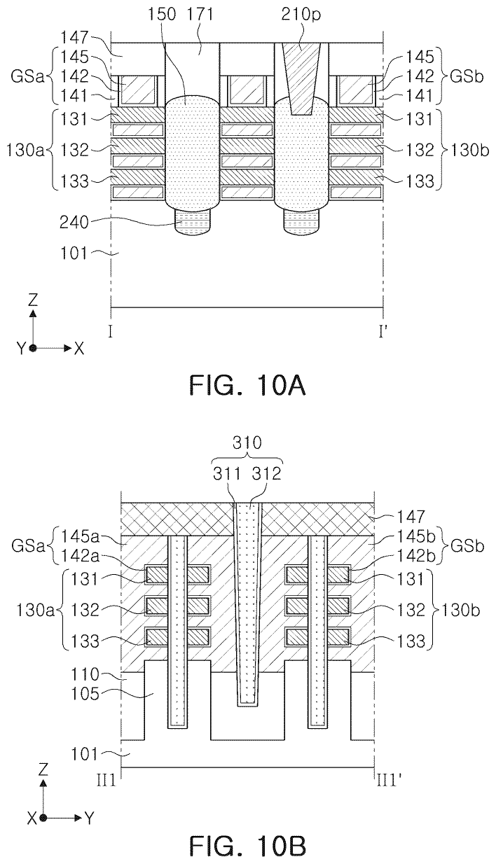

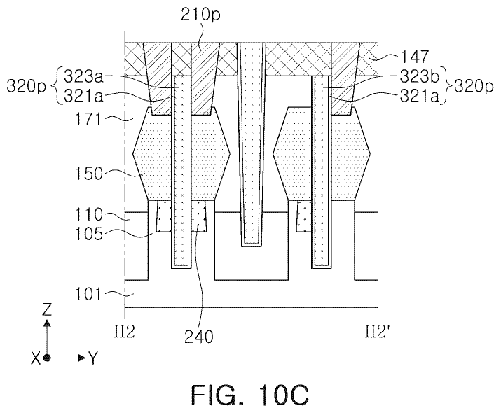

Referring to FIGS. 10A, 10B, and 10C, a preliminary frontside contact plug 210p may be formed by (at least) partially extending in (e.g., penetrating) the first interlayer insulating layer 171.

The preliminary frontside contact plug 210p may be formed to extend in (e.g., penetrate) at least a portion (e.g., the upper surface or the upper portion) of each of the first interlayer insulating layer 171 and the source/drain regions 150. The preliminary frontside contact plug 210p may include a barrier layer (not illustrated) and a conductive layer (not illustrated) filling the inner region defined by the barrier layer, but is not necessarily limited thereto, and may have a single-layer structure. The upper surface of the preliminary frontside contact plug 210p may be located at the same level as the upper surface of the first interlayer insulating layer 171.

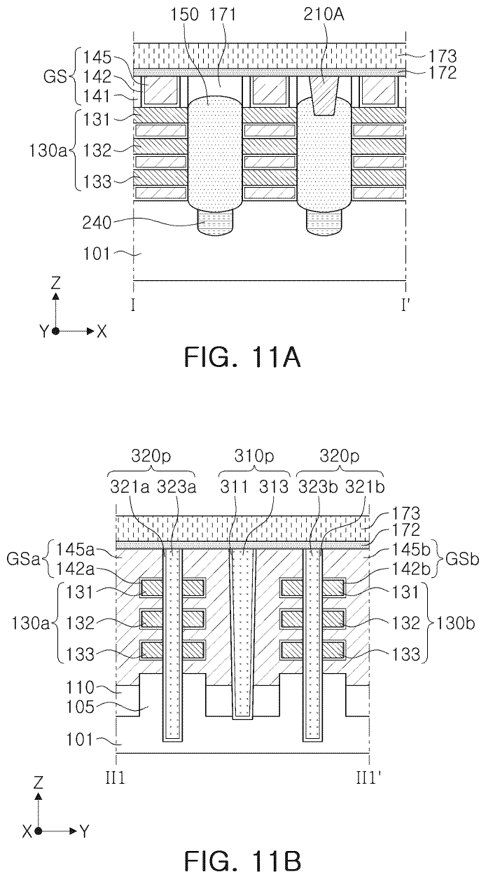

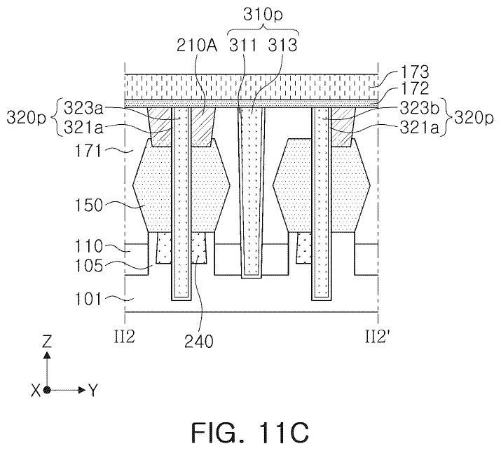

Referring to FIGS. 11A, 11B, and 11C, a frontside contact plug 210A may be formed by removing at least portions of the gate capping layer 147 and the preliminary frontside contact plug 210p, and second and third interlayer insulating layers 172 and 173 may be formed (on the frontside contact plug 210A).

The second and third interlayer insulating layers 172 and 173 may have similar characteristics to the first interlayer insulating layer 171. The second interlayer insulating layer 172 may be referred to as a buffer insulating layer 172 for protecting other layers in the process of removing the first and second separation insulating layers 313 and 323 thereafter, and may be formed to cover respective upper surfaces of the first and second gate electrodes 145a and 145b. The second interlayer insulating layer 172 may be disposed on (e.g., to cover) the respective upper surfaces of the preliminary first separation pattern 310p and the preliminary second separation pattern 320p. The buffer insulating layer 172 may include a material having a different selectivity from the first and second separation insulating layers 313 and 323. The frontside contact plug 210A may be (electrically) connected to the source/drain region 150, and the upper surface of the frontside contact plug 210A may be in contact with the lower surface of the second interlayer insulating layer 172.

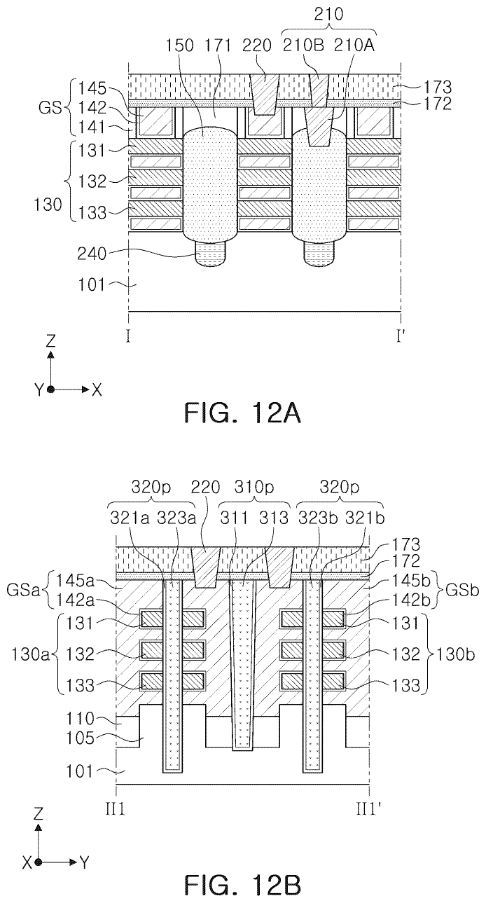

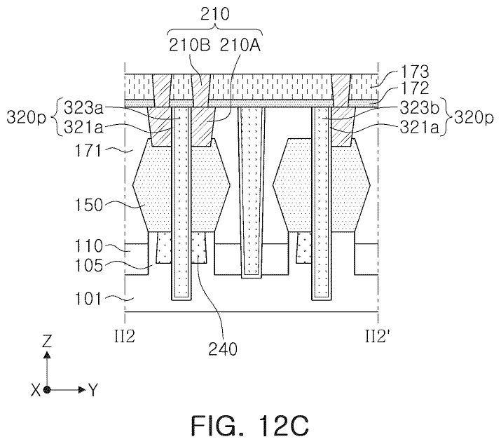

Referring to FIGS. 12A, 12B, and 12C, a frontside contact via 210B and a gate contact 220 may be formed to extend in (e.g., penetrate) at least a portion of the second and third interlayer insulating layers 172 and 173.

The frontside contact via 210B may correspond to the second portion 210B of the frontside contact structure 210, and may have the same or similar characteristics as the frontside contact plug 210A. The gate contact 220 may have similar characteristics to the frontside contact structure 210, and may extend in (e.g., penetrate) at least a portion (e.g., the upper surface or the upper portion) of each of the first gate electrode 145a and the second gate electrode 145b, and may be (electrically) connected to each of the first gate electrode 145a and the second gate electrode 145b.

Referring to FIGS. 13A, 13B, and 13C, the entire structure formed with reference to FIGS. 5A to 12C may be attached to a carrier substrate (CR), the substrate 101 may be removed, and the first insulating material layer 194 may be formed on the source/drain region 150, vertical sacrificial pattern 240, the gate dielectric layers 142, the gate electrodes 145, the device isolation layer 110, and the preliminary first and second separation patterns 310p and 320p.

The carrier substrate (CR) may be attached to the third interlayer insulating layer 173 to perform a process on the lower surface of the substrate 101 in FIGS. 13A, 13B, and 13C. In the drawings hereinafter, for the purpose of understanding, the entire structure is depicted as being rotated or flipped the structure illustrated in FIGS. 12A, 12B, and 12C upside down.

The substrate 101 may be removed from the upper surface of the substrate 101. The substrate 101 may be removed and thinned by, for example, a lapping, grinding, and/or polishing process. A portion of the (fin-shaped) active pattern 105 may be removed to form an active pattern 105 having a constant depth from the source/drain region 150. In the process of forming the active pattern 105, at least a portion of each of the upper surface and the side surface of the device isolation layer 110 may be exposed. A first insulating material layer 194 may be (at least partially) filled in the area where the substrate 101 is removed. The first insulating material layer 194 may include an insulating material, and may include silicon oxide or the like, but is not limited thereto.

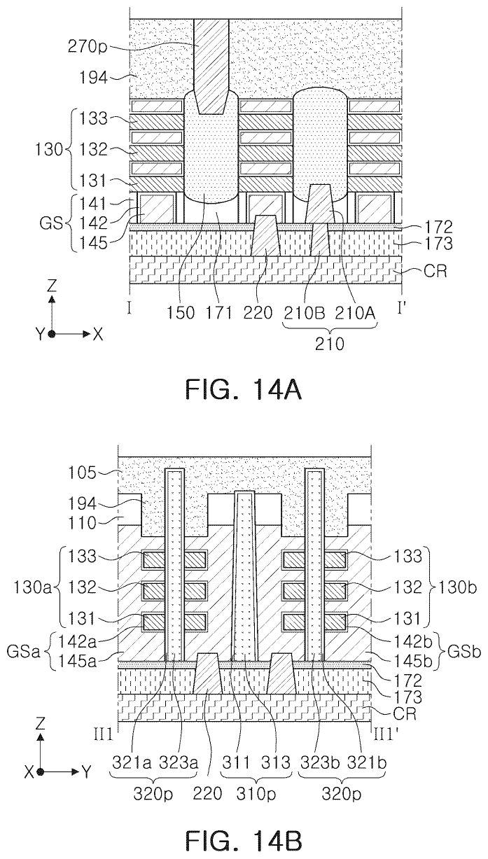

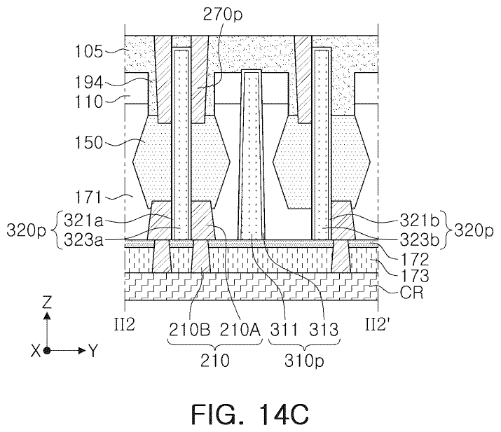

Referring to FIGS. 14A14B, and 14C, the vertical sacrificial pattern 240 may be removed, and a preliminary backside contact plug 270p may be formed.

The vertical sacrificial pattern 240 may be formed on the upper surface of the source/drain regions 150. The vertical sacrificial pattern 240 may include an active vertical sacrificial pattern that serves as a self-align element for forming the preliminary backside contact plug 270p and an inactive vertical sacrificial pattern other than the active vertical sacrificial pattern. After removing at least a portion of the substrate insulating layer 190, exposing the upper surface of the vertical sacrificial pattern 240, and removing the vertical sacrificial pattern 240 in the area where the preliminary backside contact plug 270p is to be formed, the preliminary backside contact plug 270p may be formed.

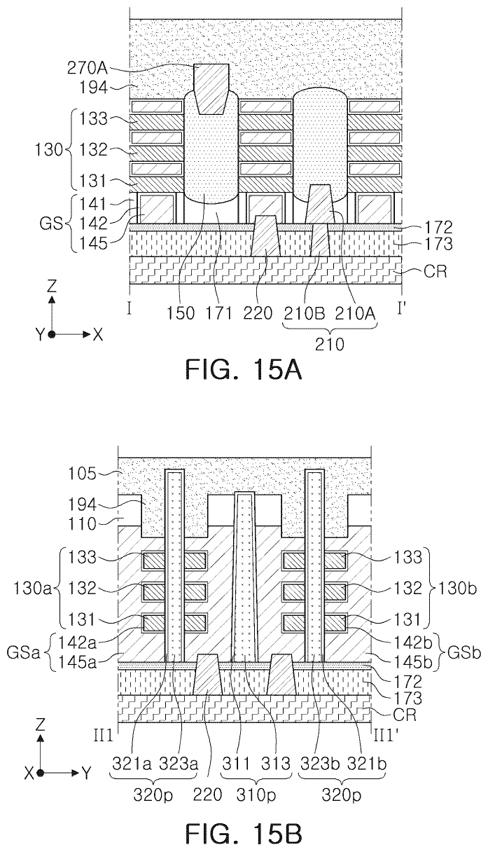

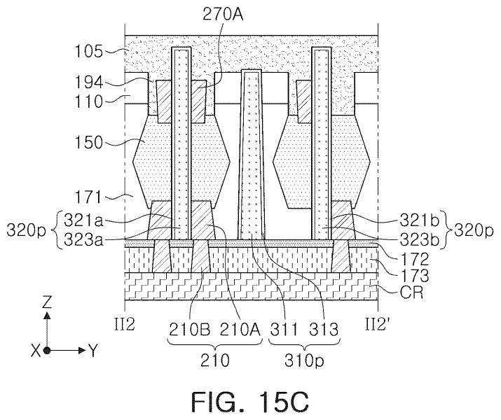

Referring to FIGS. 15A, 15B, and 15C, a portion of the substrate insulating layer 190 may be removed to expose the upper surface of the preliminary backside contact plug 270p, and a portion of the preliminary backside contact plug 270p may be removed to form the first portion 270A.

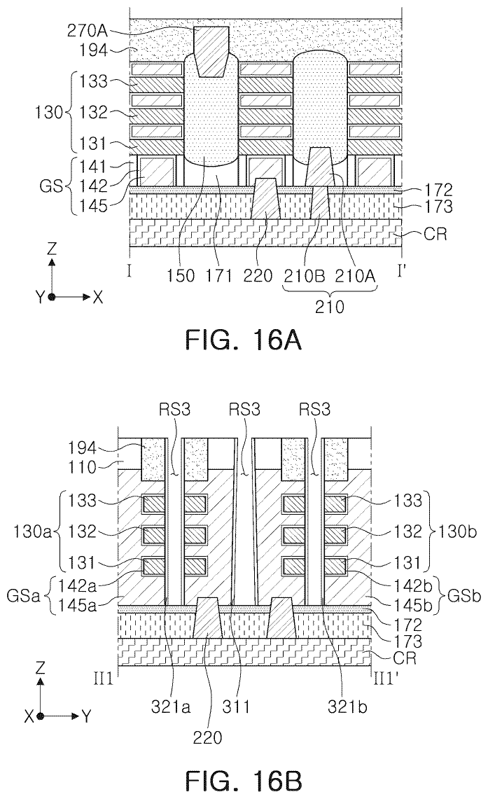

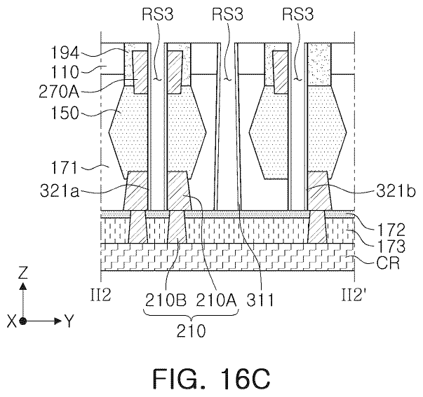

The upper end of the first portion 270A may be located at a different level from the upper end of the preliminary first and second separation patterns 310p and 320p. For example, the upper end of the first portion 270A may be located at a lower level than the upper end of each of the preliminary first and second separation patterns 310p and 320p, and according to the structure described above, even when a portion of the preliminary first and second separation patterns 310p and 320p is removed in a subsequent process (FIGS. 16A, 16B, and 16C), the first portion 270A may not be damaged. After forming the first portion 270A, the exposed upper surface may be covered with an insulating material, and the same material as the first insulating material layer 194 may be used through the same process to form a substrate insulating layer 190 without a layer boundary. However, it is not limited thereto, and the structure may be such that the layer boundary within the substrate insulating layer 190 is clearly visible. The first portion 270A may correspond to a portion of the backside contact structure 270 and may be referred to as a backside contact plug 270A.

Referring to FIGS. 16A, 16B, and 16C, a portion of the substrate insulating layer 190 may be removed, the upper surfaces of the preliminary first separation pattern 310p and the preliminary second separation pattern 320p may be exposed, and then the first and second separation insulating layers 313 and 323 may be removed to form third recessed regions RS3.

The preliminary first separation pattern 310p and the preliminary second separation pattern 320p may have different lengths (in the third direction). The length of the preliminary first separation pattern 310p may be less (shorter) than the length of the preliminary second separation pattern 320p, and the length from the upper end (e.g., upper surface) of the preliminary first separation pattern 310p to the upper end (e.g., upper surface) of the substrate insulating layer 190 (e.g., the first insulating material layer 194) may be greater than the length from the upper end (e.g., upper surface) of the preliminary second separation pattern 320p to the upper end (e.g., upper surface) of the substrate insulating layer 190. In the process, the upper end (e.g., upper surface) of the preliminary second separation pattern 320p may be exposed first, and a Chemical Mechanical Polishing (CMP) process or the like may be continuously performed until the upper end (e.g., upper surface) of the preliminary first separation pattern 310p is exposed.

The first and second separation insulating layers 313 and 323 may be removed through respective exposed upper surfaces of the preliminary first separation pattern 310p and the preliminary second separation pattern 320p. The removal process of the first and second separating insulating layers 313 and 323 may be a wet etching process, or the like. The first and second separating insulating layers 313 and 323 may include a material having a different selectivity from the first and second insulating liners 311 and 321 extending around (e.g., surrounding) the first and second separating insulating layers 313 and 323, so that the removal process may be a process for selectively removing only the first and second separating insulating layers 313 and 323. The first and second separating insulating layers 313 and 323 may include a material having a different selectivity from that of the second interlayer insulating layer 172 in contact with respective lower surfaces of the first and second separating insulating layers 313 and 323, so that the removal process may be a process for selectively removing only the first and second separating insulating layers 313 and 323.

Referring to FIGS. 17A, 17B, and 17C, a second insulating material layer 195 may be formed on the upper surface of the first insulating material layer 194, and air gap regions AG1 and AG2 may be formed within the third recessed region RS3.

The second insulating material layer 195 may include a low-κ dielectric material, and may non-conformally cover the upper surface of the first insulating material layer 194 and the third recessed region RS3 through a CVD process or the like. The low-κ dielectric material may cover the upper surface of the first insulating material layer 194, may cover only at least a portion of the entrance of the third recessed region RS3, and may not (entirely) extend along the side surface of the third recessed region RS3. The second insulating material layer 195 may include a material such as SiOCN and may cover the upper entrance of the third recessed region RS3, exposed from the first insulating material layer 194, and may form air gap regions AG1 and AG2 within the third recessed region RS3. The upper entrance of the third recessed region RS3 may be sealed by the second insulating material layer 195. For example, the second insulating material layer 195 may be on upper portions of side surfaces of the first and second insulating liners 311 and 321 to block the entrance of the third recessed region RS3. The air gap regions AG1 and AG2 may include air in the same state as the atmosphere, but is not limited thereto.

Referring to FIGS. 2A, 2B, and 2C, a semiconductor device 100A may be manufactured by forming a backside contact via 270B extending in (e.g., penetrating) at least a portion of the second insulating material layer 195 and removing the carrier substrate (CR). In a subsequent process, a rear power structure (electrically) connected to the backside contact structure 270 may be additionally formed.

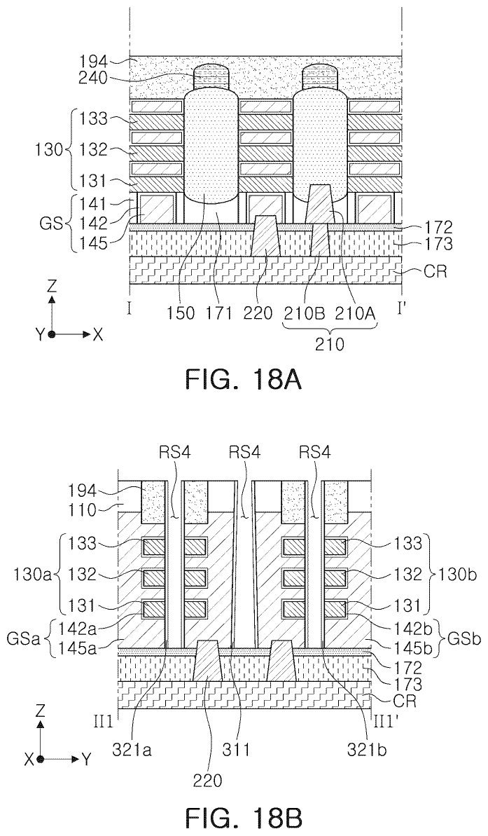

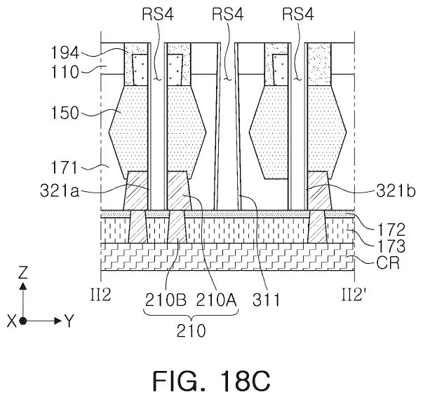

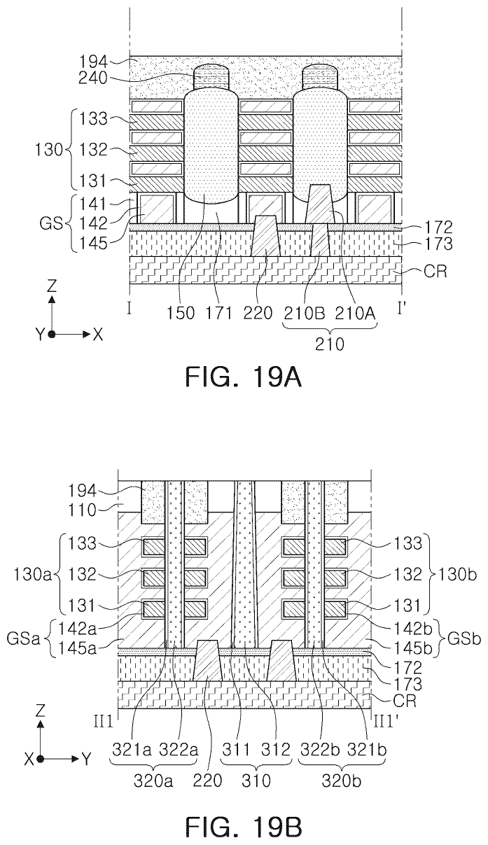

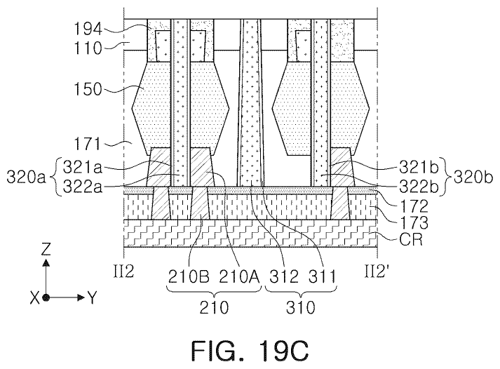

FIGS. 18A, 18B, 18C, 19A, 19B, and 19C are drawings illustrating a process for explaining a method of manufacturing a semiconductor device 100B according to example embodiments.

Referring to FIGS. 18A, 18B, and 18C, first, a front side process for forming a source/drain region 150, gate structures GSa and GSb, and frontside contact structure 210 on a substrate (see 101 of FIGS. 5A to 5C) is performed in the same manner, and then, at least a portion of the preliminary first and second separation patterns 310p and 320p may be removed to form a fourth recessed region RS4. Unlike the series of processes in FIGS. 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, and 17C described above, the fourth recessed region RS4 may be formed in a process before the backside contact structure 270 is formed. The fourth recessed region RS4 may correspond to a region defined by the first insulating liner 311 and the second insulating liners 321a and 321b. The fourth recessed region RS4 may serve to separate the vertical sacrificial pattern 240.

Referring to FIGS. 19A, 19B, and 19C, the first low-κ dielectric layer 312 (corresponding to the first separation insulating layer 312) and the second low-κ dielectric layers 322a and 322b (corresponding to the second separation insulating layers 322a and 322b) may be formed through a process of filling the fourth recessed region RS4 with a low-dielectric material. The first low-κ dielectric layer 312 and the second low-κ dielectric layers 322a and 322b may include a low-κ dielectric material having a low dielectric constant, and respective ends (e.g., upper ends and lower ends) of the first low-κ dielectric layer 312 and the second low-κ dielectric layers 322a and 322b may undergo a series of polishing or etching processes so that they are positioned at the same level as the ends (e.g., upper ends and lower ends) of the first insulating liner 311 and the second insulating liners 321a and 321b.

Referring to FIGS. 3A, 3B, and 3C, the vertical sacrificial pattern 240 may be removed to form a backside contact structure 270, and the carrier substrate (CR) may be removed to manufacture the semiconductor device 100A. In a subsequent process, a rear power structure (electrically) connected to the backside contact structure 270 may be additionally formed.

FIGS. 20A, 20B, and 20C are drawings illustrating process operations to explain a method of manufacturing a semiconductor device 100C according to example embodiments. FIGS. 20A, 20B, and 20C may correspond to cross-sections illustrating process operations corresponding to FIGS. 16A, 16B, and 16C, respectively.

Referring to FIGS. 20A, 20B, and 20C, the process described above with reference to FIGS. 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 15A, 15B, and 15C is first performed in the same manner, and then, depending on the length of the plurality of separation patterns, an etching or polishing process may be performed or stopped. As illustrated, the etching or polishing process may be performed until at least a portion of the upper surface of the long (longer or taller than the preliminary first separation pattern 310p) preliminary second separation pattern 320p is exposed.

Referring to FIGS. 4A, 4B, and 4C, in a subsequent process, through the exposed upper surface, an insulating material may be removed, and an air gap region may be formed, or a separation pattern including a low-κ material may be formed through a process of filling the area from which the insulating material has been removed with a low-κ material. These processes may be selectively applied to the area where the separation pattern structure is to be introduced.

As set forth above, according to example embodiments, a semiconductor device having improved electrical characteristics may be provided by replacing the interior of an insulating pattern separating a gate structure with a material having a low dielectric constant.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a substrate insulating layer that includes an insulating pattern, wherein the insulating pattern extends in a first direction that is parallel with a lower surface of the substrate insulating layer, and the insulating pattern protrudes in a third direction that is perpendicular to the lower surface of the substrate insulating layer;
a first gate structure that extends in a second direction that is parallel with the lower surface of the substrate insulating layer and intersects the first direction, wherein the first gate structure overlaps the insulating pattern in the third direction;
a second gate structure that extends in the second direction and is spaced apart from the first gate structure in the first direction, wherein the second gate structure overlaps the insulating pattern in the third direction;
first semiconductor patterns that are spaced apart from each other in the third direction, wherein the first gate structure extends around the first semiconductor patterns;
second semiconductor patterns that are spaced apart from each other in the third direction, wherein the second gate structure extends around the second semiconductor patterns;
a plurality of source/drain regions that includes a first source/drain region and a second source/drain region on the insulating pattern, wherein the first source/drain region is electrically connected to the first semiconductor patterns, and the second source/drain region is electrically connected to the second semiconductor patterns;
a first separation pattern that extends in the third direction between the first gate structure and the second gate structure;
a plurality of second separation patterns, ones of which extend into at least portions of the respective ones of the first semiconductor patterns and/or the respective ones of the second semiconductor patterns in the third direction; and
a backside contact structure that extends into the substrate insulating layer, wherein the backside contact structure is electrically connected to at least one of the plurality of source/drain regions,
wherein at least one of the first separation pattern and the plurality of second separation patterns includes an air gap and an insulating liner, and
wherein a side surface of the insulating liner extends along at least a portion of a boundary of the air gap.

2. The semiconductor device of claim 1, wherein the substrate insulating layer comprises: a first insulating material layer that includes an oxide; and a second insulating material layer that includes a low-κ material,
wherein the first insulating material layer is on the second insulating material layer.

3. The semiconductor device of claim 2, wherein the backside contact structure includes a first portion and a second portion,
wherein the first portion of the backside contact structure is on the second portion of the backside contact structure,
wherein the first portion of the backside contact structure is in contact with the at least one of the plurality of source/drain regions, and
wherein the second portion of the backside contact structure extends in at least a portion of the second insulating material layer.

4. The semiconductor device of claim 3, wherein an upper surface of the second portion of the backside contact structure is farther than an upper surface of the second insulating material layer from the lower surface of the substrate insulating layer in the third direction.

5. The semiconductor device of claim 1, wherein the first separation pattern and at least one of the plurality of second separation patterns extend parallel to each other in the first direction.

6. The semiconductor device of claim 1, wherein the first gate structure includes,
a first gate electrode that extends around the first semiconductor patterns; and
a first gate dielectric layer between the first gate electrode and the first semiconductor patterns and between the first gate electrode and the substrate insulating layer, and
the second gate structure includes,
a second gate electrode that extends around the second semiconductor patterns; and
a second gate dielectric layer between the second gate electrode and the second semiconductor patterns and between the second gate electrode and the substrate insulating layer.

7. The semiconductor device of claim 6, wherein an upper surface of the first separation pattern and an upper surface of at least one of the plurality of second separation patterns are coplanar with an upper surface of the first gate electrode and an upper surface of the second gate electrode, respectively.

8. The semiconductor device of claim 7, further comprising:
an interlayer insulating layer on the upper surface of the first separation pattern and the upper surface of the at least one of the plurality of second separation patterns.

9. The semiconductor device of claim 8, further comprising:
a frontside contact plug that extends into at least a portion of the interlayer insulating layer,
wherein the frontside contact plug is electrically connected to at least one of the plurality of source/drain regions.

10. The semiconductor device of claim 9, wherein the insulating liner includes a same material as a material of the interlayer insulating layer.

11. The semiconductor device of claim 1, further comprising:
a device isolation layer that extends around the insulating pattern.

12. The semiconductor device of claim 11, wherein the first separation pattern extends into at least a portion of the device isolation layer, and
wherein at least one of the plurality of second separation patterns extends into at least a portion of the insulating pattern.

13. The semiconductor device of claim 1, wherein the backside contact structure is in contact with a side surface of at least one of the plurality of second separation patterns.

14. A semiconductor device comprising:
a substrate insulating layer that includes an insulating pattern that protrudes in a direction that is perpendicular to a lower surface of the substrate insulating layer;
a first gate structure and a second gate structure on the substrate insulating layer, wherein the first gate structure and the second gate structure overlap the insulating pattern, and wherein the first gate structure and the second gate structure are spaced apart from each other;
a plurality of semiconductor patterns that are stacked and spaced apart from each other in the direction, wherein the first gate structure and/or the second gate structure extend around ones of the plurality of semiconductor patterns;
source/drain regions on the substrate insulating layer, wherein the source/drain regions are in contact with opposite side surfaces of the plurality of semiconductor patterns;
a plurality of separation patterns that are configured to separate the first gate structure and the second gate structure into a plurality of regions and electrically insulate the plurality of regions from each other; and
a backside contact plug that extends into the substrate insulating layer and is electrically connected to at least one of the source/drain regions,
wherein the plurality of separation patterns include a first separation pattern that has a first length and a second separation pattern that has a second length equal to or greater than the first length,
wherein the first separation pattern includes a first material and the second separation pattern includes a second material, and
wherein a dielectric constant of the first material is equal to or greater than a dielectric constant of the second material.

15. The semiconductor device of claim 14, wherein the second separation pattern includes an insulating liner and a low-κ region, and
wherein the low-κ region includes the second material.

16. The semiconductor device of claim 15, wherein the first material comprises silicon nitride.

17. The semiconductor device of claim 15, wherein the insulating liner includes a material having a first etch selectivity that is different from a second etch selectivity of the first material.

18. The semiconductor device of claim 15, wherein the low-κ region is an air gap region.

19. A semiconductor device comprising:
a first transistor that includes a first gate electrode, a first gate dielectric layer, a first source/drain region, a second source/drain region, and first semiconductor patterns;
a second transistor that includes a second gate electrode, a second gate dielectric layer, a third source/drain region, a fourth source/drain region, and second semiconductor patterns, wherein the second transistor is spaced apart from the first transistor;
a first separation pattern between the first transistor and second transistor, wherein the first separation pattern electrically insulates the first gate electrode and the second gate electrode from each other;
second separation patterns that extend into at least portions of the first gate electrode and the second gate electrode, wherein the second separation patterns are configured to divide each of the first gate electrode and the second gate electrode into two sub-regions; and
a backside contact plug that is electrically connected to at least one of the first source/drain region, the second source/drain region, the third source/drain region, and the fourth source/drain region,
wherein at least one of the first separation pattern and the second separation patterns includes an air gap region and an insulating liner adjacent the air gap region and extends continuously without a step.

20. The semiconductor device of claim 19, wherein the two sub-regions of the first gate electrode have different conductive types, and
wherein the two sub-regions of the second gate electrode have different conductive types.
